(19) United States
(12) Patent Application Publication
(10) Pub. No.: US 2026/0282446 A1
(43) Pub. Date: Sep. 17, 2026

(54) THIN FILM TRANSISTOR SUBSTRATE

(71) Applicant: Innolux Corporation, Miaoli County (TW)

(72) Inventors: Jhe-Ciou Jhu, Miaoli County (TW); Yu-Shan Shih, Miaoli County (TW); Wang-Cheng Chung, Miaoli County (TW)

(73) Assignee: Innolux Corporation, Miaoli County (TW)

(21) Appl. No.: 19/547,703

(22) Filed: Feb. 24, 2026

(30) Foreign Application Priority Data
Mar. 12, 2025 (CN) 202510291400.0

(51) Int. Cl. H10D 30/67

(52) U.S. Cl. CPC H10D 30/6733; H10D 30/6704

(57) ABSTRACT

The present disclosure provides a thin-film transistor substrate including a substrate, a first gate on the substrate and including a fist side and a second side, a semiconductor layer on the first gate, a second gate on the semiconductor layer and including a third side and a fourth side, a source on the semiconductor layer and adjacent to the first side and the third side, and a drain on the semiconductor layer and adjacent to the second side and the fourth side. The second gate overlaps with the first gate. The first side is distance from the second side by a first distance, the second side is distance from the fourth side by a second distance, and an absolute value of a difference between the first distance and the second distance is greater than or equal to 0 µm and is smaller than or equal to 3 µm.

### CROSS-REFERENCE TO RELATED APPLICATION

This application claims the priority benefit of China application serial no. 202510291400.0, filed on March 12, 2025. The entirety of the above-mentioned patent application is hereby incorporated by reference herein and made a part of this specification.

### BACKGROUND

### Technical Field

The present disclosure relates to a thin film transistor substrate.

### DESCRIPTION OF RELATED ART

Currently, the mainstream display devices in the market have evolved from the previous cathode-ray tubes (CRT) to flat panel displays such as liquid crystal display devices or organic light emitting diode display devices, and are widely applied in various fields. However, as electronic devices continue to develop toward lighter, thinner, shorter, and smaller aspects, and users’ requirements for the performance of the electronic devices continue to increase, researchers in the field are still continuously improving the existing display devices. For example, the thin film transistor substrate in the display device is one of the factors that affects the performance of the display device, so there is a continuous need for the researchers in the field to improve the thin film transistor substrate to meet the users’ current or future needs.

### SUMMARY

The present disclosure provides a thin film transistor substrate in which the first side of the first gate is at a first distance from the third side of the second gate above the first gate, and the second side of the first gate is at a second distance from the fourth side of the second gate, so that the parasitic capacitance between the first gate and the source and/or between the first gate and the drain (i.e., Cgs and/or Cgd) can be reduced by designing the absolute value of the difference between the first distance and the second distance to be greater than or equal to 0 µm and less than or equal to 3 µm, and thus the loading and the power consumption of the product can be reduced.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a thin film transistor substrate according to an embodiment of the present disclosure.

FIG. 2A is a schematic top view of a thin film transistor substrate according to another embodiment of the present disclosure.

FIG. 2B is a schematic cross-sectional view taken along line A-A' of FIG. 2A.

FIG. 3A is an enlarged cross-sectional schematic view of a buffer layer according to an embodiment of the present disclosure.

FIG. 3B is a curve diagram of element analysis results along line B-B' of FIG. 3A.

FIG. 4A is an enlarged cross-sectional schematic view of a buffer layer according to another embodiment of the present disclosure.

FIG. 4B is a curve diagram of element analysis results along line C-C' of FIG. 4A.

FIG. 5 is a schematic cross-sectional view of a thin film transistor substrate according to yet another embodiment of the present disclosure.

### DESCRIPTION OF THE EMBODIMENTS

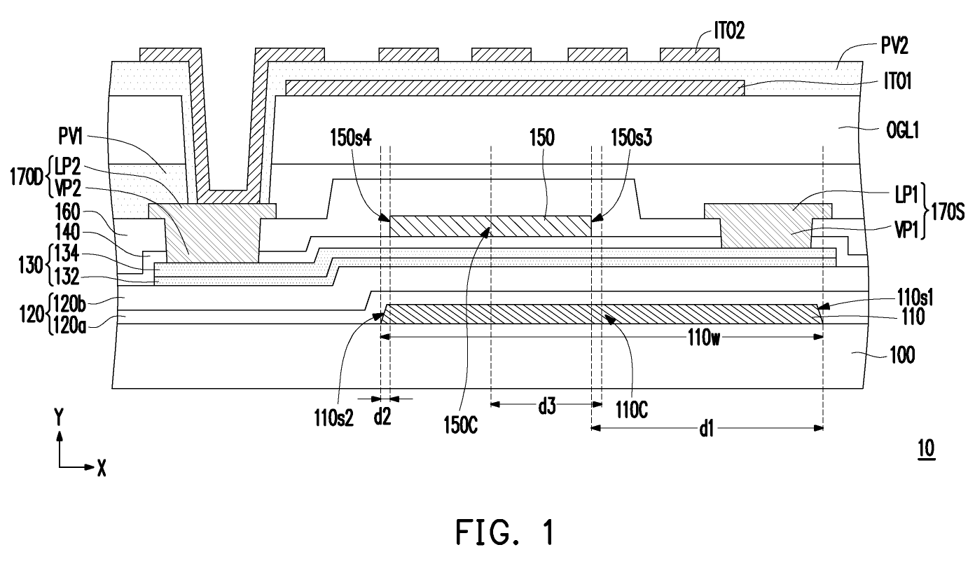

Referring to FIG. 1, a thin film transistor substrate 10 may include a substrate 100, a first gate 110, a semiconductor layer 130, a second gate 150, a source 170S, and a drain 170D. The thin film transistor substrate 10 may be included in an electronic unit. In some embodiments, the electronic unit may include chips, diodes, antenna components, sensors, structures or components formed through semiconductor-related processes, or structures or components formed on the substrate 100 through semiconductor-related processes. In some embodiments, the electronic unit may include a light-emitting component. The light-emitting component may include a light emitting diode (LED), a quantum dot (QD), a fluorescence, a phosphor, other suitable materials, or combinations thereof.

In some embodiments, the substrate 100 may include a flexible substrate and a non-flexible substrate. The material of the substrate 100 may include glass, semiconductor material, quartz, sapphire, polyimide (PI), polycarbonate (PC), polyethylene terephthalate (PET), other suitable materials, or combinations of the aforementioned materials, but is not limited thereto.

In some embodiments, the first gate 110, the second gate 150, the source 170S, the drain 170D may include any suitable conductive material. For example, the first gate 110 may include copper, aluminum, molybdenum, tungsten, gold, chromium, nickel, platinum, titanium, iridium, rhodium, alloys thereof, combinations thereof, or other metal materials with good conductivity, but is not limited thereto.

The first gate 110 is disposed on the substrate 100 and includes a first side 110s1 and a second side 110s2. In some embodiments, the first gate 110 may be electrically connected to a signal line (e.g., a scan line or a signal line providing a certain bias), but is not limited thereto.

The semiconductor layer 130 is disposed on the first gate 110. In some embodiments, the semiconductor layer 130 may include amorphous silicon, low-temp polysilicon (LTPS), metal oxide, other suitable materials, or combinations of the aforementioned materials. The metal oxide may include indium gallium zinc oxide (IGZO), indium zinc oxide (IZO), indium gallium zinc tin oxide (IGZTO), other suitable materials, or combinations of the aforementioned materials. In this embodiment, the semiconductor layer 130 may include a first sub-layer 132 and a second sub-layer 134 sequentially disposed on the first gate 110. In some embodiments, the first sub-layer 132 and the second sub-layer 134 may include different materials. In this embodiment, the zinc atomic ratio in the first sub-layer 132 and the second sub-layer 134 may be a first zinc atomic ratio (Zn1) and a second zinc atomic ratio (Zn2), respectively, and the second zinc atomic ratio is greater than the first zinc atomic ratio (Zn2 > Zn1), while the indium atomic ratio in the first sub-layer 132 and the second sub-layer 134 may be a first indium atomic ratio (In1) and a second indium atomic ratio (In2), respectively, and the first indium atomic ratio is greater than the second indium atomic ratio (In1 > In2). In some embodiments, the semiconductor layer 130 may include one layer, two layers, or three or more layers, but is not limited thereto.

The second gate 150 is disposed on the semiconductor layer 130 and includes a third side 150s3 and a fourth side 150s4. The second gate 150 may be electrically connected to a signal line (e.g., a scan line).

The source 170S is disposed on the semiconductor layer 130 and may be adjacent to the first side 110s1 of the first gate 110 and the third side 150s3 of the second gate 150. In some embodiments, the source 170S may include a first portion VP1 and a second portion LP1 on the first portion VP1, the first portion VP1 is disposed in a hole formed in the insulation layer 140 and the insulation layer 160, that is, the first portion VP1 passes through the insulation layer 140 and the insulation layer 160 to be connected to the semiconductor layer 130. The second portion LP1 is disposed on the first portion VP1, and the second portion LP1 extends onto the upper surface of the insulation layer 160 and contacts the upper surface of the insulation layer. The source 170Sis electrically connected to a data line.

The drain 170D is disposed on the semiconductor layer 130 and may be adjacent to the second side 110s2 of the first gate 110 and the fourth side 150s4 of the second gate 150. In some embodiments, the drain 170D may include a first portion VP2 and a second portion LP2 on the first portion VP2. The first portion VP2 may be electrically connected to and contact the semiconductor layer 130. The second portion LP2 may connect to the first portion VP2 and contact a pixel electrode, that is, the second portion LP2 may be electrically connected to a pixel electrode (e.g., an electrode ITO2). In some embodiments, the first portion VP2 of the drain 170D and the first portion VP1 of the source 170S may have different heights (e.g., height in the Y direction).

In this embodiment, as shown in FIG. 1, the second gate 150 overlaps with the first gate 110 in the Y direction, wherein the first side 110s1 of the first gate 110 is at a first distance d1 from the third side 150s3 of the second gate 150, and the second side 110s2 of the first gate 110 is at a second distance d2 from the fourth side 150s4 of the second gate 150. In this embodiment, the absolute value of the difference between the first distance d1 and the second distance d2 is greater than or equal to 0 µm and less than or equal to 3 µm, which can reduce the parasitic capacitance between the first gate 110 and the source 170S and/or between the first gate 110 and the drain 170D (i.e., Cgs and/or Cgd), and thereby improving the impact on the stability of the threshold voltage caused by the DIBL effect. In some embodiments, the Y direction may be substantially parallel to the normal direction of the display device or substantially parallel to the top view direction of the display device, but is not limited thereto.

In some embodiments, the parasitic capacitance value between the first gate 110 and the source 170S or the drain 170D per unit width of the semiconductor layer 130 (e.g., the minimum channel width between the source 170S and the drain 170D) may be less than or equal to 1.5 femtofarad (fF). In this embodiment, the aforementioned parasitic capacitance value may be, for example, measured by an impedance analyzer at a high frequency (e.g., greater than 1 MHz).

In some embodiments, the first gate 110 may have a first width 110w in the X direction, wherein the absolute value of the difference between the first distance d1 and the second distance d2 may be greater than or equal to 1/3 of the first width 110w and may be less than or equal to 1/2 of the first width 110w. In some embodiments, the X direction may be substantially perpendicular to the normal direction of the display device or substantially perpendicular to the top view direction of the display device, but is not limited thereto.

In some embodiments, the first gate 110 may be shifted toward the source 170S to make the absolute value of the difference between the first distance d1 and the second distance d2 within the aforementioned range. As shown in FIG. 1, when the first gate 110 is shifted toward the source 170S, the first gate 110 may overlap with the source 170S and may not overlap with the drain 170D, which may reduce the parasitic capacitance between the first gate 110 and the drain 170D (i.e., Cgd), and thereby lowering the impact of the kick-back voltage caused by the coupling effect of the parasitic capacitance on the pixel voltage. As a result, the stability of the threshold voltage can be improved. In some other embodiments, the first gate 110 may be shifted toward the drain 170D, such that the first gate 110 may overlap with the drain 170D and may not overlap with the source 170S, making the absolute value of the difference between the first distance d1 and the second distance d2 within the aforementioned range, which can reduce the parasitic capacitance between the first gate 110 and the source 170S (i.e., Cgs). In some embodiments, the first distance d1 may be less than or equal to 3 µm, but is not limited thereto. In some alternative embodiments, the first gate 110 may overlap with the source 170S and have a first overlap width, the first gate 110 may overlap with the drain 170D and have a second overlap width (not shown), and the second overlap width is smaller than the first overlap width, making the absolute value of the difference between the first distance d1 and the second distance d2 within the aforementioned range, which can reduce the parasitic capacitance between the first gate 110 and the drain 170D (i.e., Cgd), and thereby lowing the impact of the kick-back voltage caused by the coupling effect of the parasitic capacitance on the pixel voltage. As a result, the stability of the threshold voltage can be improved.

In this embodiment, the first gate 110 may have a first center 110C in the X direction, and the second gate 150 may have a second center 150C in the X direction, and the first center 110C does not overlap with the second center 150C in the top view direction. In some embodiments, the horizontal distance d3 between the first center 110C and the second center 150C may be in the range of 1 µm to 3 µm.

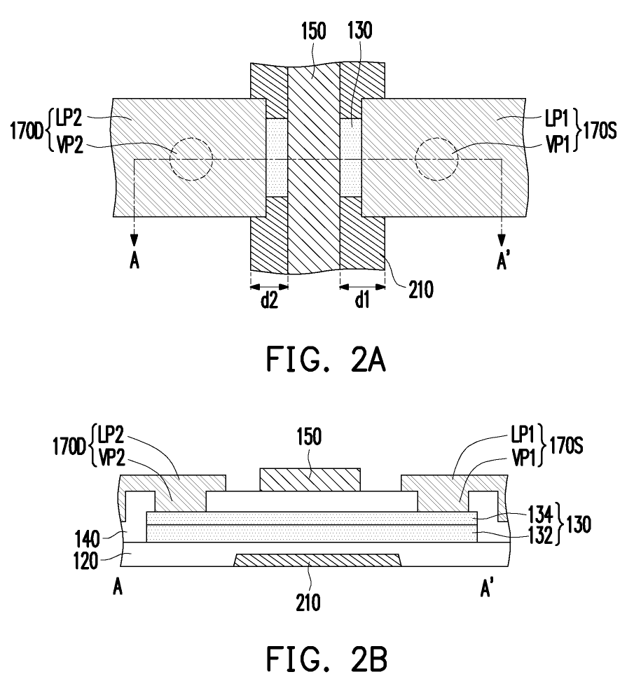

In some embodiments, as shown in FIG. 2A and FIG. 2B, the width of the first gate 210 may be greater than the width of the second gate 150, and the first gate 210 may not overlap with the source 170S and the drain 170D, which can reduce the parasitic capacitance between the first gate 210 and the source 170S and the drain 170D (i.e., Cgd and Cgs). In this embodiment, the first center of the first gate 210 in the X direction (e.g., the extending direction of line A-A') does not overlap with the second center of the second gate 150 in the X direction in the top view direction.

In some embodiments, the parasitic capacitance value between the first gate 210 and the source 170S or the drain 170D per unit width of the semiconductor layer 130 may be less than or equal to 1.5 femtofarad (fF). In this embodiment, the aforementioned parasitic capacitance value may be, for example, measured by an impedance analyzer at high frequency (e.g., greater than 1 MHz). In some embodiments, the first distance d1 and/or the second distance d2 may be less than or equal to 3 µm.

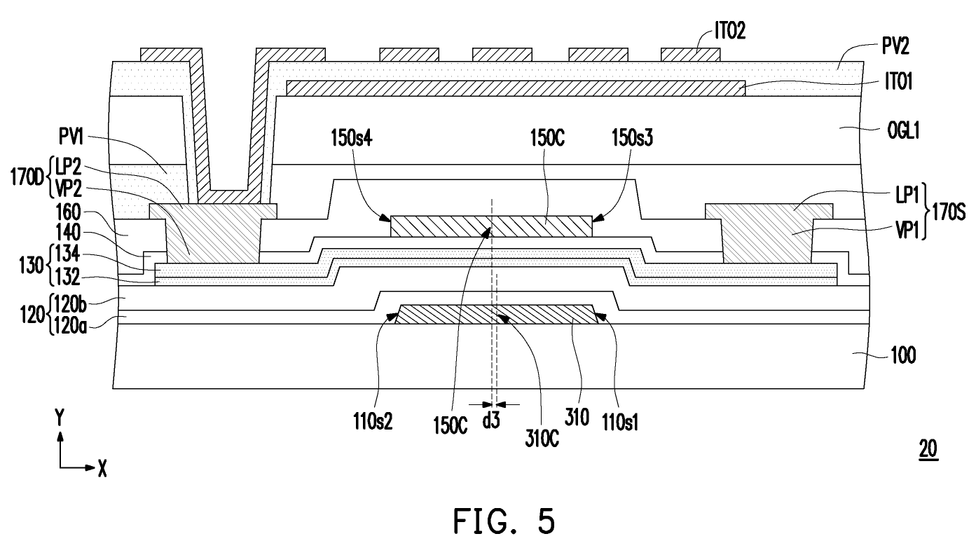

In some other embodiments, as shown in the thin film transistor substrate 20 in FIG. 5, the first gate 310 may not overlap with the source 170S and the drain 170D, which can further reduce the parasitic capacitance between the first gate 310 and the source 170S and the drain 170D (i.e., Cgd and Cgs). In this embodiment, the first gate 310 may have a first center 310C, and the second gate 150 may have a second center 150C, and the first center 310C does not overlap with the second center 150C in the top view direction. In some embodiments, the horizontal distance d3 between the first center 310C and the second center 150C may be in the range of 1 µm to 3 µm.

In some embodiments, the parasitic capacitance between the first gate 110 and the source 170S and/or the drain 170D (i.e., Cgs and/or Cgd) can be reduced by adjusting the thickness of the insulation layer (e.g., the buffer layer 120 shown in FIG. 1) between the first gate 110 and the source 170S and/or the drain 170D and/or the material ratio of each sub-layer in the insulation layer.

In some embodiments, the thin film transistor substrate 10 may further include a buffer layer 120 between the first gate 110 and the semiconductor layer 130, wherein the thickness of the buffer layer 120 is in the range of 300 nm to 2500 nm.

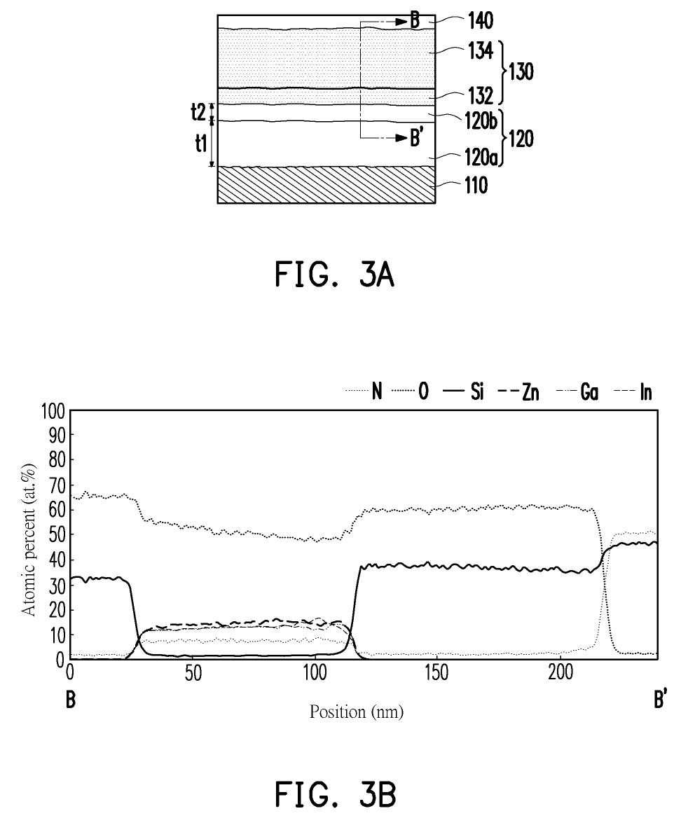

In some embodiments, the buffer layer 120 may include a first sub-layer 120a and a second sub-layer 120b sequentially disposed on the first gate 110. In this embodiment, as shown in FIG. 3A and FIG. 3B, the thickness of the first sub-layer 120a and the second sub-layer 120b may be t1 and t2, respectively, and t1 > t2. The first sub-layer 120a and the second sub-layer 120b may include different materials. The nitrogen atomic ratio in the first sub-layer 120a and the second sub-layer 120b may be a first nitrogen atomic ratio (N1) and a second nitrogen atomic ratio (N2,) respectively, and the first nitrogen atomic ratio is greater than the second nitrogen atomic ratio (N1 > N2), while the oxygen atomic ratio in the first sub-layer 120a and the second sub-layer 120b may be a first oxygen atomic ratio (O1) and a second oxygen atomic ratio (O2), respectively, and the second oxygen atomic ratio is greater than the first oxygen atomic ratio (O2 > O1). In some embodiments, the first sub-layer 120a may include nitride (e.g., silicon nitride), while the second sub-layer 120b may include oxide (e.g., silicon oxide).

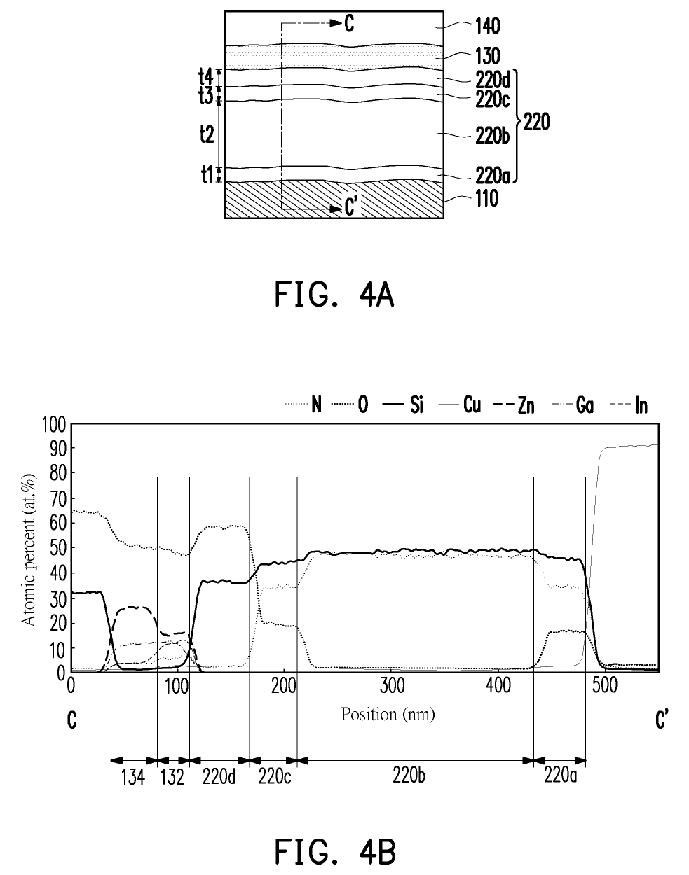

In other embodiments, as shown in FIG. 4A and FIG. 4B, the buffer layer 220 may include a first sub-layer 220a, a second sub-layer 220b, a third sub-layer 220c, and a fourth sub-layer 220d sequentially disposed on the first gate 110. In this embodiment, the thickness t2 of the second sub-layer 220b is greater than the thickness t4 of the fourth sub-layer 220d (t2 > t4), the thickness t4 of the fourth sub-layer 220d is greater than the thickness t1 of the first sub-layer 220a (t4 > t1), the thickness t1 of the first sub-layer 220a is greater than or equal to the thickness t3 of the third sub-layer 220b (t1 ≥ t3), but not limited thereto. In this embodiment, the definition of the thickness of the sub-layer may be the shortest distance of a layer in one direction (e.g., Y direction) under a cross-section. In this embodiment, the nitrogen atomic ratio N2' of the second sub-layer 220b is greater than the nitrogen atomic ratio N3' of the third sub-layer 220c, the nitrogen atomic ratio N3' of the third sub-layer 220c is greater than or equal to the nitrogen atomic ratio N1' of the first sub-layer 220a, the nitrogen atomic ratio N1' of the first sub-layer 220a is greater than the nitrogen atomic ratio N4' of the fourth sub-layer 220d (i.e., N2' > N3' ≥ N1' > N4'), but the present disclosure is not limited thereto. The oxygen atomic ratio O4' of the fourth sub-layer 220d is greater than the oxygen atomic ratio O3' of the third sub-layer 220c, the oxygen atomic ratio O3' of the third sub-layer 220c is greater than or equal to the oxygen atomic ratio O1' of the first sub-layer 220a, the oxygen atomic ratio O1' of the first sub-layer 220a is greater than the oxygen atomic ratio O2' of the second sub-layer 220b (i.e., O4' > O3' ≥ O1' > O2'), but the present disclosure is not limited thereto. In some embodiments, the first sub-layer 220a may include oxynitride (e.g., silicon oxynitride), the second sub-layer 220b may include nitride (e.g., silicon nitride), the third sub-layer 220c may include oxynitride (e.g., silicon oxynitride), and the fourth sub-layer 220d may include oxide (e.g., silicon oxide).

As shown in FIG. 4B, the zinc atomic ratio in the first sub-layer 132 and the second sub-layer 134 of the semiconductor layer 130 may be zinc atomic ratio Zn1' and zinc atomic ratio Zn2', respectively, and the zinc atomic ratio Zn2' is greater than the zinc atomic ratio Zn1' (Zn2' > Zn1'), while the indium atomic ratio in the first sub-layer 132 and the second sub-layer 134 may be indium atomic ratio In1' and indium atomic ratio In2', respectively, and the indium atomic ratio In1' is greater than the indium atomic ratio In2' (In1' > In2').

In some embodiments, as shown in FIG. 1, the thin film transistor substrate 10 may include an insulation layer 140 between the second gate 150 and the semiconductor layer 130. The insulation layer 140 may include suitable insulation material or dielectric material. For example, the insulation layer 140 may include dielectric materials such as silicon nitride (SiNx), silicon oxide (SiOx), silicon oxynitride (SiON), aluminum oxide (Al₂O₃), titanium oxide (TiO₂), tantalum oxide (Ta₂O₅), hafnium oxide (HfO₂), zirconium oxide (ZrO₂), or rare earth oxides (e.g., erbium oxide (Er₂O₃) or yttrium oxide (Y₂O₃)), or combinations of the above materials, but are not limited thereto.

In some embodiments, the thin film transistor substrate 10 may include an insulation layer 160 covering the second gate 150. In some embodiments, the insulation layer 160 may include suitable insulation material or dielectric material. For example, the insulation layer 160 may include silicon nitride (SiNx), silicon oxide (SiOx), or combinations thereof.

In some embodiments, the thin film transistor substrate 10 may include a passivation layer PV1 disposed on the insulation layer 160 and covering the source 170S and the drain 170D. According to some embodiments, the material of the passivation layer PV1 may include an inorganic material, but is not limited thereto. For example, the inorganic material may include silicon nitride, silicon oxide, silicon oxynitride, other suitable materials, or combinations thereof, but is not limited thereto. In some embodiments, the material for the passivation layer PV1 may also include rare earth oxides such as erbium oxide (Er₂O₃) or yttrium oxide (Y₂O₃).

In some embodiments, the thin film transistor substrate 10 may include an organic layer OGL1 disposed on the passivation layer PV1. According to some embodiments, the organic layer OGL1 may be a photoresist material, but is not limited thereto. For example, the organic layer OGL1 may include epoxy resins, acrylic resins such as polymethylmetacrylate (PMMA), benzocyclobutene (BCB), polyimide, perfluoroalkoxy alkane (PFA), other suitable materials, or combinations thereof, but is not limited thereto.

According to some embodiments, the electrode ITO1, the electrode ITO2 may include a conductive material. For example, the electrode ITO1, the electrode ITO2 may include indium tin oxide (ITO), tin oxide (SnO), indium zinc oxide (IZO), indium gallium zinc oxide (IGZO), indium tin zinc oxide (ITZO), antimony tin oxide (ATO), antimony zinc oxide (AZO), combinations thereof, or any other suitable conductive oxide materials. In some embodiments, the materials of the electrode ITO2 and the electrode ITO1 may be the same as or different from each other.

In some embodiments, the thin film transistor substrate 10 may include an electrode ITO1 disposed on the organic layer OGL1. In some embodiments, the thin film transistor substrate 10 may include a passivation layer PV2 covering the electrode ITO1. According to some embodiments, the material of the passivation layer PV2 may include an inorganic material, but is not limited thereto. For example, the inorganic material may include silicon nitride, silicon oxide, silicon oxynitride, other suitable materials, or combinations thereof, but is not limited thereto. In some embodiments, the materials of the passivation layer PV2 and the passivation layer PV1 may be the same as or different from each other.

In some embodiments, the thin film transistor substrate 10 may include an electrode ITO2 disposed on the passivation layer PV2. The electrode ITO2 may include a wiring connected to the drain 170D. In some embodiments, the wiring may include a portion penetrating through the organic layer OGL1, the passivation layer PV1, and the passivation layer PV2 to be in contact with the drain 170D. In some embodiments, the electrode ITO2 may be a pixel electrode, but is not limited thereto.

In summary, in the thin film transistor substrate of the embodiments of the present disclosure, the absolute value of the difference between the first distance and the second distance is designed to be greater than or equal to 0 µm and less than or equal to 3 µm, which can reduce the parasitic capacitance between the first gate and the source and/or between the first gate and the drain (i.e., Cgs and/or Cgd), and thereby improving the impact on the stability of the threshold voltage (Vt) caused by the DIBL effect.

What is claimed is:

1. A thin film transistor substrate, comprising:
a substrate;
a first gate disposed on the substrate and comprising a first side and a second side;
a semiconductor layer disposed on the first gate;
a second gate disposed on the semiconductor layer and comprising a third side and a fourth side;
a source disposed on the semiconductor layer and adjacent to the first side and the third side; and
a drain disposed on the semiconductor layer and adjacent to the second side and the fourth side,
wherein the second gate overlaps with the first gate, the first side is at a first distance from the third side, the second side is at a second distance from the fourth side, an absolute value of a difference between the first distance and the second distance is greater than or equal to 0 µm and less than or equal to 3 µm.

2. The thin film transistor substrate according to claim 1, wherein the first gate has a first width, the absolute value of the difference between the first distance and the second distance is greater than or equal to 1/3 of the first width and less than or equal to 1/2 of the first width.

3. The thin film transistor substrate according to claim 1, wherein the first distance and/or the second distance is less than or equal to 3 µm.

4. The thin film transistor substrate according to claim 1, wherein the first gate overlaps with the source, and the first gate does not overlap with the drain.

5. The thin film transistor substrate according to claim 1, wherein the first gate overlaps with the drain, and the first gate does not overlap with the source.

6. The thin film transistor substrate according to claim 1, wherein the first gate does not overlap with the drain, and the first gate does not overlap with the source.

7. The thin film transistor substrate according to claim 6, wherein a width of the first gate is greater than a width of the second gate.

8. The thin film transistor substrate according to claim 1, further comprises:
a buffer layer between the first gate and the semiconductor layer, and a thickness of the buffer layer is in a range from 300 nm to 2500 nm.

9. The thin film transistor substrate according to claim 1, wherein a parasitic capacitance value between the first gate and the source or the drain is less than or equal to 1.5 femtofarad (fF) per unit width of the semiconductor layer.

10. The thin film transistor substrate according to claim 9, wherein the parasitic capacitance value is a value measured at a frequency greater than 1 MHz in an impedance analyzer.

11. The thin film transistor substrate according to claim 1, wherein the first gate overlaps with the source and has a first overlap width, the first gate overlaps with the drain and has a second overlap width, and the first overlap width is greater than the second overlap width.

12. The thin film transistor substrate according to claim 1, wherein the first gate has a first center, the second gate has a second center, the first gate does not overlap with the source and the drain, and the first center does not overlap with the second center in a top view direction.

13. The thin film transistor substrate according to claim 12, wherein a horizontal distance between the first center and the second center is in a range from 1 µm to 3 µm.

14. The thin film transistor substrate according to claim 1, further comprising:
a buffer layer disposed between the first gate and the semiconductor layer and comprising a first sub-layer, a second sub-layer, a third sub-layer, and a fourth sub-layer sequentially disposed on the first gate, wherein:
thicknesses of the first sub-layer, the second sub-layer, the third sub-layer, and the fourth sub-layer are t1, t2, t3 and t4, respectively, and t2 > t4 > t1 ≥ t3;
nitrogen atomic ratios in the first sub-layer, the second sub-layer, the third sub-layer, and the fourth sub-layer are N1', N2', N3' and N4', respectively, and N2' > N3' ≥ N1' > N4'; and
oxygen atomic ratios in the first sub-layer, the second sub-layer, the third sub-layer and the fourth sub-layer are O1', O2', O3' and O4', respectively, and O4' > O3' ≥ O1' > O2'.

15. The thin film transistor substrate according to claim 14, wherein the first sub-layer comprises oxynitride, the second sub-layer comprises nitride, the third sub-layer comprises oxynitride, and the fourth sub-layer comprises oxide.

16. The thin film transistor substrate according to claim 1, wherein the semiconductor layer comprises a first sub-layer and a second sub-layer sequentially disposed on the first gate, wherein:
zinc atomic ratios in the first sub-layer and the second sub-layer are a first zinc atomic ratio and a second zinc atomic ratio, respectively, and the second zinc atomic ratio is greater than the first zinc atomic ratio; and
indium atomic ratios in the first sub-layer and the second sub-layer are a first indium atomic ratio and a second indium atomic ratio, respectively, and the first indium atomic ratio is greater than the second indium atomic ratio.
